(19) United States
(12) Patent Application Publication
(10) Pub. No.: US 2021/0257439 A1
(43) Pub. Date: Aug. 19, 2021

(54) METAL LAYER ON DISPLAY PANEL, AND DISPLAY PANEL

(71) Applicant: Shenzhen Royole Technologies Co., Ltd., Shenzhen (CN)

(72) Inventors: Huanda Wu, Shenzhen (CN); Tsu Chiang Chang, Shenzhen (CN)

(21) Appl. No.: 17/246,913

(22) Filed: May 3, 2021

Related U.S. Application Data
(63) Continuation of application No. PCT/CN2018/114128, filed on Nov. 6, 2018.

(51) Int. Cl. H01L 27/32

(52) U.S. Cl. CPC H01L 27/3276

(57) ABSTRACT

A metal layer and a display panel are provided. The metal layer includes a first frame strip, a second frame strip, and a wiring portion between the first and second frame strips. An input portion is disposed on the first frame strip. The wiring portion includes a first wiring group, a second wiring group, and a third wiring group. The second frame strip includes a first, a second and a third connecting portion. The first wiring group is connected between the first frame strip and the first connecting portion, the second wiring group is connected between the first frame strip and the second connecting portion, and the third wiring group is connected between the first frame strip and the third connecting portion. The first connecting portion is connected to the third connecting portion, and the second connecting portion is spaced apart from the first and third connecting portions.

### CROSS-REFERENCE TO RELATED APPLICATIONS

This application is a continuation-application of International (PCT) Patent Application No. PCT/CN2018/114128, filed on Nov. 6, 2018, and entitled “metal layer of display panel, and display panel”, the entire contents of which are incorporated herein by reference.

### TECHNICAL FIELD

The present disclosure relates to the technical field of display panels, and in particular, relates to a metal layer of a display panel and the display panel.

### BACKGROUND

An active-matrix organic light-emitting diode (AMOLED) panel is driven by a current. In the panel, a voltage drop (IRDrop) is present and caused by the current, such that drive voltage ELVDDs (pixel drive voltages) of pixels in different regions have different voltage values.

In a related AMOLED panel, as illustrated in FIG. 1, two input points 11 (ELVDD inputs) of the pixel drive voltage are disposed at the bottom of a source-drain electrode (SD) metal layer proximal to a lower boarder of the panel, an active display region (AA region) 12 on the metal layer employs comb-shaped wiring, the wirings are connected via a shorting bar 13 at the top of the SD metal layer connect. In this design, the voltage drop above the input points of ELVDD is lower than that at other positions, and as a result, uniformity of ELVDD in the panel is poor.

### SUMMARY

A metal layer of a display panel according to an embodiment of the present disclosure includes a first frame strip and a second frame strip that are disposed to face each other, and a wiring portion disposed between the first frame strip and the second frame strip and within an active display region on the display panel. At least one input portion is disposed on a side of the first frame strip far from the second frame strip, the input portion forming an input point of pixel drive voltage. The wiring portion includes a first wiring group, a second wiring group, and a third wiring group disposed adjacently. A pixel drive voltage of the first wiring group is greater than that of the second wiring group, a pixel drive voltage of the second wiring group is greater than that of the third wiring group. The second frame strip includes a first connecting portion, a second connecting portion, and a third connecting portion disposed respectively corresponding to the first wiring group, the second wiring group, and the third wiring group, the first wiring group is connected to the first frame strip and the first connecting portion and opposite to the input portion, the second wiring group is connected to the first frame strip and the second connecting portion, and the third wiring group is connected to the first frame strip and the third connecting portion; the first connecting portion is connected to the third connecting portion, and the second connecting portion is spaced apart from the first connecting portion and the third connecting portion.

A display panel according to an embodiment of the present disclosure includes a panel substrate and the metal layer as described above, wherein the metal layer is disposed on the panel substrate.

### BRIEF DESCRIPTION OF THE DRAWINGS

The present disclosure is further described with reference to the accompanying drawings and exemplary embodiments.

FIG. 1 is a schematic structural view of an SD metal layer on a conventional panel.

FIG. 2 is a schematic structural view of a metal layer according to a first embodiment of the present disclosure.

FIG. 3 is a schematic structural view of a metal layer according to a second embodiment of the present disclosure.

FIG. 4 is a schematic structural view of a metal layer according to a third embodiment of the present disclosure.

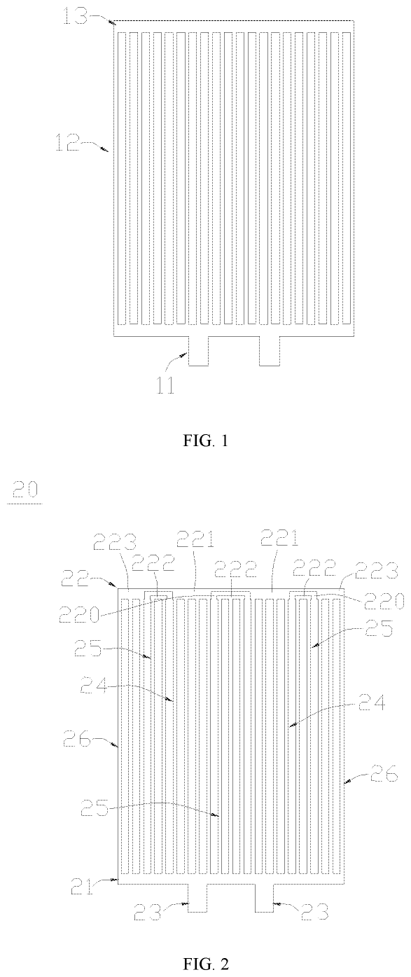

### DETAILED DESCRIPTION

For clearer descriptions of the technical features, objectives, and the technical effects of the present disclosure, the specific embodiments of the present disclosure are hereinafter described with reference to the accompanying drawings.

As illustrated in FIG. 2, a first embodiment of the present disclosure provides a metal layer 20 of an AMOLED panel. The metal layer 20 includes a first frame strip 21 and a second frame strip 22, and wiring portions disposed between the first frame strip 21 and the second frame strip 22 and on an active display region of the panel.

At least one input portion 23 is disposed on a side of the first frame strip 21 far from the second frame strip 22. The input portion 23 forms an input point of pixel drive voltage, and a pixel drive voltage (ELVDD) is input from the input portion 23 to the metal layer 20. In the wiring portion, the pixel drive voltage of the wiring portion more proximal to the input portion 23 is higher, and the pixel drive voltage is lower when the wiring portion is far from the input portion 23. A peripheral shape of the second frame strip 22 may be consistent with a peripheral shape of the first frame strip 21.

The wiring portion includes a first wiring group 24, a second wiring group 25, and a third wiring group 26 that are disposed adjacently. At least one first wiring group 24, at least one second wiring group 25, and at least one third wiring group 26 are disposed. The second frame strip 22 includes a first connecting portion 221, a second connecting portion 222, and a third connecting portion 223 that are disposed corresponding to the first wiring group 24, the second wiring group 25, and the third wiring group 26.

The first wiring group 24 is arranged between the first frame strip 21 and the first connecting portion 221 and corresponding to the input portion 23, the second wiring group 25 is arranged between the first frame strip 21 and the second connecting portion 222, and the third wiring group 26 is arranged between the first frame strip 21 and the third connecting portion 223. The first connecting portion 221 is connected to the third connecting portion 223. The second connecting portion 222 is spaced apart from the first connecting portion 221, and the second connecting portion 222 is spaced apart from the third connecting portion 223.

In combination with variations of the pixel drive voltage at various positions of the wiring portion, a pixel drive voltage of the first wiring group 24 is greater than that of the second wiring group 25, the pixel drive voltage of the second wiring group 25 is greater than that of the third wiring group 26. The third connecting portion 223 is connected to the first connecting portion 221, such that the first wiring group 24 with a maximum pixel drive voltage is connected to the third wiring group 26 with a minimum pixel drive voltage, thereby addressing the problems of uniformity of ELVDD and voltage drop (IRDrop) of the panel.

The first wiring group 24 includes a plurality of first metal wires that are spaced apart from each other and parallel to each other; the second wiring group 25 includes a plurality of second metal wires that are spaced apart from each other and parallel to each other; and the third wiring group 26 includes a plurality of third metal wires that are spaced apart from each other and parallel to each other. The first metal wires, the second metal wires, and the third metal wires are spaced apart from each other and parallel to each other to form a comb-shaped wiring portion.

Specifically, in this embodiment, as illustrated in FIG. 2, two input portions 23 are disposed on a side of the first frame strip 21 far from the second frame strip 22. The two input portions 23 are spaced apart from each other and are proximal to a center position of the first frame strip 21 and far from two end portions of the first frame strip 21.

Corresponding to the two input portions 23, the wiring portion includes two first wiring groups 24. In addition, the wiring portion includes three second wiring groups 25 and two third wiring groups 26. The second frame strip 22 correspondingly includes two first connecting portions 221, three second connecting portions 222, and two third connecting portions 223.

The two first wiring groups 24 are respectively correspond to the two input portions 23 and arranged between the first frame strip 21 and the first connecting portions 221. The two third wiring groups 26 are disposed on two opposite sides of the wiring portion and between the first frame strip 21 and the third connecting portions 223. In the three second wiring groups 25, one second wiring group 25 is disposed between the two first wiring group 24 and connected to the first frame strip 21 and the second connecting portions 222; and the other two second wiring group 25 are disposed between the first wiring groups 24 and the third wiring groups 26 and respectively connected to the first frame strip 21 and the second connecting portions 222.

The first connecting portion 221 and the third connecting portion 223 are connected to form an integral structure, such that the first wiring group 24 and the third wiring group 26 are connected together. A recessed portion 220 is formed between both of the two first connecting portions 221 and is also formed between the first connecting portion 221 and the third connecting portion 223, and the second connecting portion 222 is disposed in the corresponding recessed portion 220 and is not connected to the first connecting portion 221 or the third connecting portion 223.

In the metal layer of the panel according to this embodiment, the pixel drive voltage is input from the input portion 23 and then input to the first wiring group 24, the second wiring group 25, and the third wiring group 26 via the first frame strip 21. Since the first wiring group 24 is more proximal to the input portion 23, and the third wiring group 26 is most far from the input portion 23, the pixel drive voltage of the first wiring group 24 is the maximum and the voltage drop is smallest, and the pixel drive voltage of the third wiring group 26 is the minimum and the voltage drop is greatest. The first connecting portion 221 at the top is connected to the third connecting portion 223 at the top, such that the first wiring group 24 and the third wiring group 26 are connected, and the pixel drive voltages of the two are made uniform, thus uniformity of the pixel drive voltage on the panel is improved, and the voltage drop on the panel is reduced.

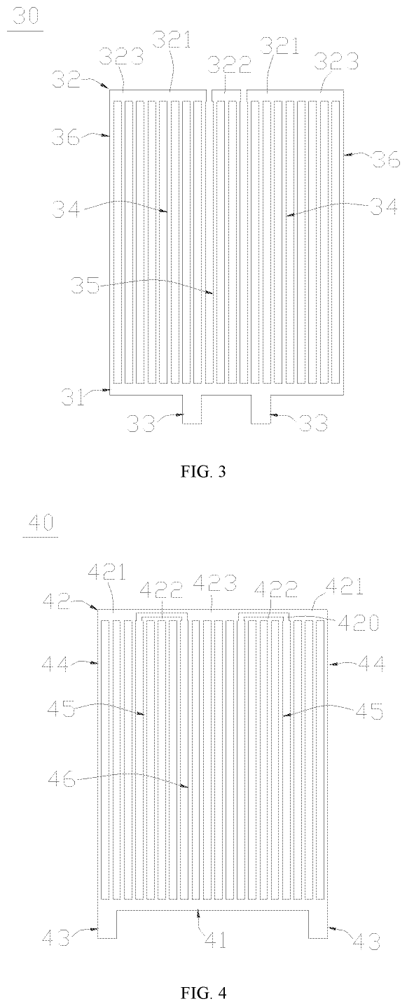

As illustrated in FIG. 3, a second embodiment of the present disclosure provides a metal layer 30 of an AMOLED panel. The metal layer 30 includes a first frame strip 31 and a second frame strip 32 that are disposed oppositely to each other, wiring portions disposed between the first frame strip 31 and the second frame strip 32 and on an active display region of the panel.

At least one input portion 33 is disposed on a side of the first frame strip 31 far from the second frame strip 32. The input portion 33 forms an input point of pixel drive voltage, and a pixel drive voltage is input from the input portion 33 to the metal layer 30. In the wiring portion, the pixel drive voltage of the wiring portion more proximal to the input portion 33 is higher, and the pixel drive voltage is lower when the wiring portion is far from the input portion 23. A peripheral shape of the second frame strip 32 may be consistent with that of the first frame strip 31.

The wiring portion includes a first wiring group 34, a second wiring group 35, and a third wiring group 36 that are adjacently disposed. At least one first wiring group 34, at least one second wiring group 35, and at least one third wiring group 36 are disposed. The second frame strip 32 includes a first connecting portion 321, a second connecting portion 322, and a third connecting portion 323 that are disposed corresponding to the first wiring group 34, the second wiring group 35, and the third wiring group 36.

The first wiring group 34 is disposed between the first frame strip 31 and the first connecting portion 321 and opposite to input portion 33, the second wiring group 35 is disposed between the first frame strip 31 and the second connecting portion 322, and the third wiring group 36 is disposed between the first frame strip 31 and the third connecting portion 323. The first connecting portion 321 is connected to the third connecting portion 323, and the second connecting portion 322 is spaced apart from the first connecting portion 321 and the third connecting portion 323.

In combination with variations of the pixel drive voltage at various positions of the wiring portion, a pixel drive voltage of the first wiring group 34 is greater than that of the second wiring group 35, pixel drive voltage of the second wiring group 35 is greater than that of the third wiring group 36. The third connecting portion 323 is connected to the first connecting portion 321, such that the first wiring group 34 with a maximum pixel drive voltage is connected to the third wiring group 36 with a minimum pixel drive voltage, thereby addressing the problems of uniformity of ELVDD and voltage drop (IRDrop) of the panel.

The first wiring group 34 includes a plurality of first metal wires that are spaced apart from each other and parallel to each other; the second wiring group 35 includes a plurality of second metal wires that are spaced apart from each other and parallel to each other; and the third wiring group 36 includes a plurality of third metal wires that are spaced apart from each other and parallel to each other. The first metal wires, the second metal wires, and the third metal wires are parallel to each other to form a comb-shaped wiring portion.

Specifically, in this embodiment, as illustrated in FIG. 3, two input portions 33 are disposed on a side of the first frame strip 31 far from the second frame strip 32. The two input portions 33 are spaced apart from each other and are proximal to a center position of the first frame strip 31 and far from two end portions of the first frame strip 31.

The wiring portion includes two first wiring groups 34, one second wiring group 35, and two third wiring groups 36. Corresponding to the wiring portion, the second frame strip 32 includes two first connecting portions 321, one second connecting portion 322, and two third connecting portions 323.

The two first wiring groups 34 are corresponding respectively to the two input portions 33 and connected to the first frame strip 31 and the first connecting portions 321. The two third wiring groups 36 are disposed on two opposing sides of the wiring portion and connected to the first frame strip 31 and the third connecting portions 323. The second wiring group 35 is disposed between the two first wiring groups 34, and is connected to the first frame strip 31 and the third connecting portion 323.

The first connecting portion 321 and the third connecting portion 323 are adjacently connected to form an integral structure; and the second connecting portion 322 is spaced apart from the two first connecting portions 321. In the perspective of structure, the second frame strip 32 is divided into three parts. A middle part of the second frame strip 32 is the second connecting portion 322, and two side parts are the first connecting portion 321 and the third connecting portion 323 that are integrally formed.

In the metal layer of the panel according to this embodiment, the pixel drive voltage is input from the input portion 33 and then input to the first wiring group 34, the second wiring group 35, and the third wiring group 36 via the first frame strip 31. Since the first wiring group 34 is more proximal to the input portion 33, and the third wiring group 36 is most far from the input portion 33, the pixel drive voltage of the first wiring group 34 is the maximum and the voltage drop is small, and the pixel drive voltage of the third wiring group 36 is the minimum and the voltage drop is greater. The first connecting portion 321 at the top is connected to the third connecting portion 323 at the top, such that the first wiring group 34 and the third wiring group 36 are connected, and the pixel drive voltages of the two are made uniform, then uniformity of the pixel drive voltage on the panel is improved, and the voltage drop on the panel is reduced.

As illustrated in FIG. 4, a third embodiment of the present disclosure provides a metal layer 40 of an AMOLED panel. The metal layer 40 includes a first frame strip 41 and a second frame strip 42, and wiring portions disposed between the first frame strip 41 and the second frame strip 42 and on an active display region of the panel.

At least one input portion 43 is disposed on a side of the first frame strip 41 far from the second frame strip 42. The input portion 43 forms an input point of pixel drive voltage, and a pixel drive voltage is input from the input portion 43 to the metal layer 40. In the wiring portion, the pixel drive voltage of the wiring portion more proximal to the input portion 43 is higher, and the pixel drive voltage is lower when the wiring portion is far from the input portion 43. A peripheral shape of the second frame strip 42 may be consistent with a peripheral shape of the first frame strip 41.

The wiring portion includes a first wiring group 44, a second wiring group 45, and a third wiring group 46 that are adjacently disposed. At least one first wiring group 44, at least one second wiring group 45, and at least one third wiring group 46 are disposed. The second frame strip 42 includes a first connecting portion 421, a second connecting portion 422, and a third connecting portion 423 that are disposed corresponding to the first wiring group 44, the second wiring group 45, and the third wiring group 46.

The first wiring group 44 is disposed between the first frame strip 41 and the first connecting portion 421 and opposite to the input portion 43, the second wiring group 45 is disposed between the first frame strip 41 and the second connecting portion 422, and the third wiring group 46 is disposed between the first frame strip 41 and the third connecting portion 423. The first connecting portion 421 is connected to the third connecting portion 423, and the second connecting portion 422 is spaced apart from the first connecting portion 421 and the third connecting portion 423.

In combination with variations of the pixel drive voltage at various positions of the wiring portion, a pixel drive voltage of the first wiring group 44 is greater than that of the second wiring group 45, pixel drive voltage of the second wiring group 45 is greater than that of the third wiring group 46. The third connecting portion 423 is connected to the first connecting portion 421, such that the first wiring group 44 with a maximum pixel drive voltage is connected to the third wiring group 46 with a minimum pixel drive voltage, thereby addressing the problems of uniformity of ELVDD and voltage drop (IRDrop) of the panel.

The first wiring group 44 includes a plurality of first metal wires that are spaced apart from each other and parallel to each other; the second wiring group 45 includes a plurality of second metal wires that are spaced apart from each other and parallel to each other; and the third wiring group 46 includes a plurality of third metal wires that are spaced apart from each other and parallel to each other. The first metal wires, the second metal wires, and the third metal wires are parallel to each other to form a comb-shaped wiring portion.

Specifically, in this embodiment, as illustrated in FIG. 4, two input portions 43 are disposed on a side of the first frame strip 41 far from the second frame strip 42. The two input portions 43 are disposed at two opposing end portions of the first frame strip 41.

The wiring portion includes two first wiring groups 44, two second wiring groups 45, and one third wiring group 46. Corresponding to the wiring portion, the second frame strip 42 includes two first connecting portions 421, two second connecting portions 422, and one third connecting portion 423.

The two first wiring groups 44 are disposed on two opposing sides (that is, two outermost sides of the wiring portion) of the wiring portion, are respectively corresponding to the two input portions 43, and are connected between the first frame strip 41 and the first connecting portions 421. The third wiring group 46 is disposed at a middle position of the wiring portion and connected to the first frame strip 41 and the third connecting portion 423. The two second wiring groups 45 are respectively disposed between the first wiring groups 44 and the third wiring group 46 and connected to the first frame strip 41 and the second connecting portions 422.

The first connecting portion 421 and the third connecting portion 423 are connected to form an integral structure, such that the first wiring group 44 and the third wiring group 46 are connected. A recessed portion 420 is formed between the first connecting portion 421 and the third connecting portion 423, and the second connecting portion 422 is disposed in the recessed portion 420 and is not connected to the first connecting portion 421 or the third connecting portion 423.

In the metal layer of the panel according to this embodiment, the pixel drive voltage is input from the input portion 43 and then input to the first wiring group 44, the second wiring group 45, and the third wiring group 46 via the first frame strip 41. Since the first wiring group 44 is most proximal to the input portion 43, and the third wiring group 46 is most far from the input portion 43, the pixel drive voltage of the first wiring group 44 is the maximum and the voltage drop is small, and the pixel drive voltage of the third wiring group 46 is the minimum and the voltage drop is greater. The first connecting portion 421 at the top is connected to the third connecting portion 423 at the top, such that the first wiring group 44 and the third wiring group 46 are connected, and the pixel drive voltages of the two are made uniform, uniformity of the pixel drive voltage on the panel is improved, and the voltage drop on the panel is reduced.

An AMOLED panel according to the present disclosure includes a panel substrate and the metal layer as described in any of the above embodiments. The metal layer is disposed on the panel substrate, and is mainly an SD metal layer on the panel.

According to the present disclosure, by configuration of the metal layer, the problem of poor uniformity of ELVDD in the AMOLED panel is addressed.

Described above are exemplary embodiments of the present disclosure, but are not intended to limit the scope of the present disclosure. Any equivalent structure or equivalent process variation made based on the specification and drawings of the present disclosure, which is directly or indirectly applied in other related technical fields, fall within the scope of the present disclosure.

1. A metal layer of a display panel, comprising:
a first frame strip and a second frame strip disposed oppositely to each other, and
a wiring portion disposed between the first frame strip and the second frame strip and within an active display region on the display panel;
wherein at least one input portion is disposed on a side of the first frame strip far from the second frame strip, the input portion forming an input point of pixel drive voltage;
wherein the wiring portion comprising a first wiring group, a second wiring group, and a third wiring group disposed adjacently, a pixel drive voltage of the first wiring group is greater than that of the second wiring group, a pixel drive voltage of the second wiring group is greater than that of the third wiring group; and
wherein the second frame strip comprising a first connecting portion, a second connecting portion, and a third connecting portion disposed respectively corresponding to the first wiring group, the second wiring group, and the third wiring group, the first wiring group is connected to the first frame strip and the first connecting portion and opposite to the input portion, the second wiring group is connected to the first frame strip and the second connecting portion, and the third wiring group is connected to the first frame strip and the third connecting portion; the first connecting portion is connected to the third connecting portion, and the second connecting portion is spaced apart from the first connecting portion and the third connecting portion.

2. The metal layer according to claim 1, wherein two input portions are disposed on the side of the first frame strip far from the second frame strip; the two input portions are spaced apart from each other and proximal to a center position of the first frame strip.

3. The metal layer according to claim 2, wherein the wiring portion comprises two first wiring groups, three second wiring groups, and two third wiring groups; and the second frame strip correspondingly comprises two first connecting portions, three second connecting portions, and two third connecting portions;
the two first wiring groups are respectively corresponding to the two input portions and connected to the first frame strip and the first connecting portions; the two third wiring groups are disposed on two opposite sides of the wiring portion and connected to the first frame strip and the third connecting portions; and the three second wiring groups are respectively disposed between the two first wiring groups and between the first wiring groups and the third wiring groups, and connected to the first frame strip and the second connecting portions.

4. The metal layer according to claim 3, wherein the first connecting portions and the third connecting portions are connected to form an integral structure; recessed portions are respectively formed between the two first connecting portions and between one of the first connecting portions and corresponding one of the third connecting portions, and each of the second connecting portions is disposed in the corresponding recessed portion.

5. The metal layer according to claim 2, wherein the wiring portion comprises two first wiring groups, one second wiring group, and two third wiring groups; and the second frame strip correspondingly comprises two first connecting portions, one second connecting portion, and two third connecting portions;
the two first wiring groups are respectively opposite to the two input portions and connected to the first frame strip and the first connecting portions; the two third wiring groups are disposed on two opposite sides of the wiring portion and respectively connected to the first frame strip and the third connecting portions; and the second wiring group is disposed between the two first wiring portions and connected to the first frame strip and the second connecting portion.

6. The metal layer according to claim 5, wherein one first connecting portion and corresponding one third connecting portion are adjacently connected to form an integral structure; and the second connecting portion is spaced apart from the two first connecting portions.

7. The metal layer according to claim 1, wherein two input portions are disposed on a side of the first frame strip far from the second frame strip; the two input portions are disposed at two opposing end portions of the first frame strip.

8. The metal layer according to claim 7, wherein the wiring portion comprises two first wiring groups, two second wiring groups, and one third wiring group; and the second frame strip correspondingly comprises two first connecting portions, two second connecting portions, and one third connecting portion;
the two first wiring groups are respectively disposed on two opposite sides of the wiring portion, and respectively connected to the first frame strip and the first connecting portions; the third wiring group is disposed at a middle portion of the wiring portion and is connected to the first frame strip and the third connecting portion; the two second wiring groups are respectively disposed between the first wiring groups and the third wiring group, and connected to the first frame strip and the second connecting portions.

9. The metal layer according to claim 8, wherein the first connecting portion and the third connecting portion are connected to form an integral structure; a recessed portion is formed between the first connecting portion and the third connecting portion, and the second connecting portion is disposed in the recessed portion.

10. The metal layer according to claim 1, wherein the first wiring group comprises a plurality of first metal wires that are spaced apart from each other and parallel to each other; the second wiring group comprises a plurality of second metal wires that are spaced apart from each other and parallel to each other; and the third wiring group comprises a plurality of third metal wires that are spaced apart from each other and parallel to each other;
the first metal wires, the second metal wires, and the third metal wires are spaced apart from each other and parallel to each other.

11. A display panel, comprising a panel substrate and a metal layer, wherein the metal layer is disposed on the panel substrate;
the metal layer comprising a first frame strip and a second frame strip disposed oppositely to each other, and a wiring portion disposed between the first frame strip and the second frame strip and within an active display region on the display panel; wherein at least one input portion is disposed on a side of the first frame strip far from the second frame strip, the input portion forming an input point of pixel drive voltage;
the wiring portion comprising a first wiring group, a second wiring group, and a third wiring group disposed adjacently, a pixel drive voltage of the first wiring group is greater than that of the second wiring group, a pixel drive voltage of the second wiring group is greater than that of the third wiring group; and
the second frame strip comprising a first connecting portion, a second connecting portion, and a third connecting portion disposed respectively corresponding to the first wiring group, the second wiring group, and the third wiring group, the first wiring group is connected to the first frame strip and the first connecting portion and opposite to the input portion, the second wiring group is connected to the first frame strip and the second connecting portion, and the third wiring group is connected to the first frame strip and the third connecting portion; the first connecting portion is connected to the third connecting portion, and the second connecting portion is spaced apart from the first connecting portion and the third connecting portion.

12. The display panel according to claim 11, wherein two input portions are disposed on the side of the first frame strip far from the second frame strip; the two input portions are spaced apart from each other and proximal to a center position of the first frame strip.

13. The display panel according to claim 12, wherein the wiring portion comprises two first wiring groups, three second wiring groups, and two third wiring groups; and the second frame strip correspondingly comprises two first connecting portions, three second connecting portions, and two third connecting portions;
the two first wiring groups are respectively corresponding to the two input portions and connected to the first frame strip and the first connecting portions; the two third wiring groups are disposed on two opposite sides of the wiring portion and connected to the first frame strip and the third connecting portions; and the three second wiring groups are respectively disposed between the two first wiring groups and between the first wiring groups and the third wiring groups, and connected to the first frame strip and the second connecting portions.

14. The display panel according to claim 13, wherein the first connecting portions and the third connecting portions are connected to form an integral structure; recessed portions are respectively formed between the two first connecting portions and between one of the first connecting portions and corresponding one of the third connecting portions, and each of the second connecting portions is disposed in the corresponding recessed portion.

15. The display panel according to claim 12, wherein the wiring portion comprises two first wiring groups, one second wiring group, and two third wiring groups; and the second frame strip correspondingly comprises two first connecting portions, one second connecting portion, and two third connecting portions;
the two first wiring groups are respectively opposite to the two input portions and connected to the first frame strip and the first connecting portions; the two third wiring groups are disposed on two opposite sides of the wiring portion and respectively connected to the first frame strip and the third connecting portions; and the second wiring group is disposed between the two first wiring portions and connected to the first frame strip and the second connecting portion.

16. The display panel according to claim 15, wherein one first connecting portion and corresponding one third connecting portion are adjacently connected to form an integral structure; and the second connecting portion is spaced apart from the two first connecting portions.

17. The display panel according to claim 11, wherein two input portions are disposed on a side of the first frame strip far from the second frame strip; the two input portions are disposed at two opposing end portions of the first frame strip.

18. The display panel according to claim 17, wherein the wiring portion comprises two first wiring groups, two second wiring groups, and one third wiring group; and the second frame strip correspondingly comprises two first connecting portions, two second connecting portions, and one third connecting portion;
the two first wiring groups are respectively disposed on two opposite sides of the wiring portion, and respectively connected to the first frame strip and the first connecting portions; the third wiring group is disposed at a middle portion of the wiring portion and is connected to the first frame strip and the third connecting portion; the two second wiring groups are respectively disposed between the first wiring groups and the third wiring group, and connected to the first frame strip and the second connecting portions.

19. The display panel according to claim 18, wherein the first connecting portion and the third connecting portion are connected to form an integral structure; a recessed portion is formed between the first connecting portion and the third connecting portion, and the second connecting portion is disposed in the recessed portion.

20. The display panel according to claim 11, wherein the first wiring group comprises a plurality of first metal wires that are spaced apart from each other and parallel to each other; the second wiring group comprises a plurality of second metal wires that are spaced apart from each other and parallel to each other; and the third wiring group comprises a plurality of third metal wires that are spaced apart from each other and parallel to each other;
the first metal wires, the second metal wires, and the third metal wires are spaced apart from each other and parallel to each other.
